(19) United States
(12) Patent Application Publication
(10) Pub. No.: US 2025/0030390 A1
(43) Pub. Date: Jan. 23, 2025

(54) Cascode Amplifier with Improved High Frequency Linearity

(71) Applicant: Texas Instruments Incorporated, Dallas, TX (US)

(72) Inventors: Vysakh K, Kerala (IN); Shagun Dusad, Bangalore (IN); Rajendrakumar Joish, Bangalore (IN)

(21) Appl. No.: 18/678,818

(22) Filed: May 30, 2024

(30) Foreign Application Priority Data
Jul. 20, 2023 (IN) 202341048792

(51) Int. Cl. H03F 3/45

(52) U.S. Cl. CPC H03F 3/45192; H03F 3/45094

(57) ABSTRACT

A cascode amplifier including an amplifier transistor, a cascode transistor, and a current injection circuit. The amplifier transistor has a first current terminal receiving a first power supply voltage, a second current terminal, and a control terminal receiving an input signal. The cascode transistor has a first current terminal coupled to the second current terminal of the amplifier transistor, a second current terminal coupled to an output terminal; and a control terminal receiving a bias voltage. The current injection circuit has an input receiving the input signal, and first and second outputs coupled to the first and second current terminals of the cascode transistor, respectively. The current injection circuit is configured to present out-of-phase currents to the cascode transistor responsive to the input signal.

### BACKGROUND

This specification relates to amplifier circuits, and more particularly to cascode stage amplifier circuits.

The cascode amplifier is a common type of electronic amplifier, due to its favorable gain and impedance characteristics. In general, cascode amplifiers include an amplifier stage that receives the input signal, and a cascode stage that produces the output signal.

FIG. 1A shows prior art cascode amplifier 100, in this example implemented using metal-oxide-semiconductor (MOS) transistors, specifically n-channel MOS (NMOS) transistors 102, 104. NMOS transistor 102 provides the amplifier stage in cascode amplifier 100, and NMOS transistor 104 provides the cascode stage. NMOS transistor 102 is common-source connected, with its source terminal coupled to circuit ground and its gate terminal coupled to input terminal VIN. NMOS transistor 104 is common-gate connected, with its source terminal coupled to the drain terminal of NMOS transistor 102 and its gate terminal coupled to bias voltage terminal VBIAS. Load device 105 has one terminal coupled to power supply terminal VDD and another terminal coupled to the drain terminal of NMOS transistor 104. Output terminal VOUT from cascode amplifier 100 is at the drain terminal of NMOS transistor 104.

Cascode amplifiers can similarly be constructed using p-channel MOS (PMOS) transistors arranged as a common-source amplifier stage and a common-gate cascode stage. Bipolar junction transistors (BJT) may also implement a cascode amplifier using a common-emitter amplifier stage and a common-base cascode stage.

In both the MOS and BJT implementations, cascode amplifiers eliminate direct coupling between output and input, thus improving input-output isolation over single transistor amplifier stages. In addition, the cascode arrangement provides high voltage gain, and improved bandwidth and linearity, over simpler amplifier stage designs such as common-source and common-emitter amplifiers. Cascode amplifiers are often used in high frequency applications, such as communications receivers, high frequency test and measurement equipment such as spectrum analyzers, and the like.

### SUMMARY

According to an example, a circuit includes a first transistor having a first current terminal coupled to a first power supply terminal, a second current terminal, and a control terminal coupled to an input terminal; a second transistor having a first current terminal coupled to the second current terminal of the first transistor, a second current terminal coupled to an output terminal, and a bias terminal coupled to a bias terminal; and a current injection circuit having an input coupled to the input terminal, a first output coupled to the second current terminal of the second transistor, and a second output coupled to the first current terminal of the second transistor.

According to another example, a cascode amplifier includes an amplifier transistor having a first current terminal receiving a first power supply voltage, a second current terminal, and a control terminal receiving an input signal; a cascode transistor having a first current terminal coupled to the second current terminal of the amplifier transistor, a second current terminal coupled to an output terminal; and a control terminal receiving a bias voltage; and a current injection circuit having an input receiving the input signal, and first and second outputs coupled to the first and second current terminals of the cascode transistor, respectively, the current injection circuit configured to present out-of-phase currents from its first and second outputs responsive to the input signal.

According to another example, a method includes applying an input signal to an amplifier transistor of a cascode amplifier, the cascode amplifier further including a cascode transistor coupled to the input transistor; responsive to the input signal, generating out-of-phase injection currents from first and second outputs of a current injection circuit; applying the out-of-phase injection currents to first and second current terminals of the cascode transistor; and generating an output signal from an output of the cascode amplifier responsive to the input signal.

Example technical advantages enabled by one or more of these examples include reduced distortion in the output signal of the cascode amplifier due to the effects of non-linear current conducted by the cascode transistor. Improved intermodulation distortion performance, especially at high frequencies, can be attained, with minimal increase in power consumption.

Other example technical advantages enabled by this disclosure are apparent to those of ordinary skill in the art having reference to the following specification together with its drawings.

### BRIEF DESCRIPTION OF THE DRAWINGS

FIG. 1A is an electrical diagram, in schematic form, of a prior art cascode amplifier.

FIG. 1B is an electrical diagram, in schematic form, of another prior art cascode amplifier.

FIG. 2 is an electrical diagram, in block and schematic form, of an example cascode amplifier.

FIG. 3 is an electrical diagram, in schematic form, of an example current injection circuit coupled into the example cascode amplifier of FIG. 2.

FIG. 4A is a flow diagram illustrating example operation of the cascode amplifier of FIG. 2.

FIG. 4B is a flow diagram illustrating example operation of the current injection circuit in the cascode amplifier of FIG. 3.

FIG. 5A and FIG. 5B are plots illustrating third-order intermodulation distortion performance of the example cascode amplifier of FIG. 3.

The same reference numbers or other reference designators are used in the drawings to illustrate the same or similar (in function and/or structure) features.

### DETAILED DESCRIPTION

As described above, the cascode amplifier is an attractive amplifier configuration for a wide range of electronic circuits and systems, due to its high voltage gain, the decoupling of its output from its input, and its generally linear operation. Some non-idealities are present in cascode amplifiers, however. For example, non-linearities are present in the transistor drain-source or collector-emitter currents, and can degrade the linearity of the amplifier transfer function, especially at higher frequencies. In many cases, particularly in the MOS context, the overall linearity of the cascode amplifier has previously been considered as primarily determined by the linearity of the common-source stage. Prior art approaches have addressed the linearity of the common-source stage of the MOS cascode amplifier, treating the common-gate stage as an ideal current source.

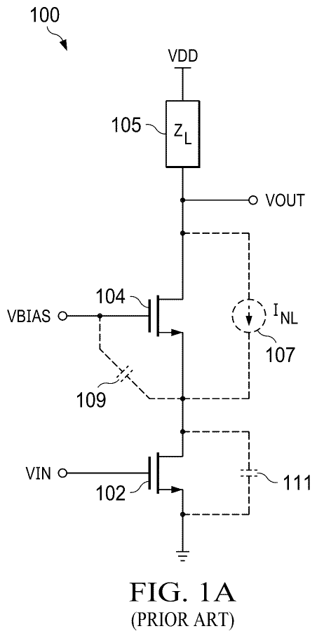

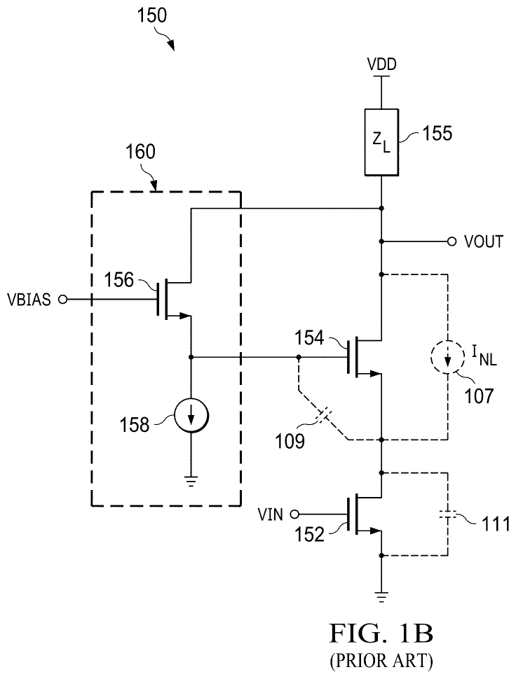

However, non-linear conduction by the common-gate or cascode stage of the cascode amplifier has now been observed to limit the overall linearity of the amplifier, especially at the higher frequencies now commonly encountered in applications such as communications receivers. Non-linearity in the source-drain current conducted by common-gate NMOS transistor 104 of prior art MOS cascode amplifier 100 is modeled in the schematic diagram of FIG. 1A by a current source 107 conducting a non-linear current I_{NL}. This non-linear current I_{NL} can affect the output signal at terminal VOUT by “leaking” through parasitic capacitances of transistors 102, 104, particularly the parasitic gate-to-source capacitance 109 between the gate and source of transistor 104 and the parasitic capacitance 111 between the drain and source of transistor 102 as shown in FIG. 1A. As the frequency of the input signal at terminal VIN increases, the leakage of non-linear current I_{NL} through parasitic capacitances 109 and 111 increases, which in turn increases the injection of non-linear current through load 105 and results in distortion of the output signal at terminal VOUT.

FIG. 1B illustrates another example prior art cascode amplifier 105. Prior art cascode amplifier 150 includes common-source NMOS transistor 152, common-gate NMOS transistor 154, load 155, NMOS transistor 156 and current source 158. NMOS transistor 152 has a source terminal at circuit ground, a gate terminal receiving input signal VIN, and a drain terminal coupled to a source terminal of NMOS transistor 154. A drain terminal of NMOS transistor 154 is coupled to one terminal of load device 155, which has its other terminal coupled to the VDD power supply terminal. The output signal from cascode amplifier 150 is presented from the drain terminal of NMOS transistor 154 at output terminal VOUT.

NMOS transistor 156 and current source 158 form a current buffer 160 at the gate terminal of common-gate transistor 154 in the arrangement of FIG. 1B. A drain terminal of NMOS transistor 156 is coupled to the drain terminal of common-gate transistor 154 and to load device 155, and a source terminal of NMOS transistor 156 is coupled to the gate terminal of common-gate transistor 154 and to one terminal of current source 158. As such, the gate terminal of common-gate NMOS transistor 154 receives its bias voltage from the source of NMOS transistor 156 rather than directly. A gate terminal of NMOS transistor 156 receives a bias voltage at bias terminal VBIAS. A second terminal of current source 158 is coupled to a common potential (e.g., circuit ground). Current source 158 may be implemented as a MOS transistor receiving a controlled or regulated gate voltage, or in a leg of a current mirror, or otherwise configured to conduct a selected fixed current.

In this circuit, current buffer 160 establishes a buffered current that is fed to or conducted from the output of cascode amplifier 150. As a result, the portion of non-linear current I_{NL} that leaks through parasitic gate-to-source capacitance 109 in the operation of cascode amplifier 150 does not leak to the amplifier output. Considering the small-signal operation of cascode amplifier 150, current buffer 160 effectively forms a local loop for the portion of non-linear current I_{NL} conducted through parasitic gate-to-source capacitance 109 (which is an AC short circuit at high frequency), which reduces the non-linear current that is fed to the output and distorts the output signal. However, the portion of non-linear current I_{NL} that leaks through parasitic drain-to-source capacitance 111 of common-source transistor 152 is not isolated from the output by current buffer 160. Moreover, given the relatively large capacitance of gate-to-source capacitance 109, current buffer 160 must conduct significant bias current to effectively buffer the non-linear current I_{NL} from the amplifier output.

It is within this context that the embodiments described herein arise.

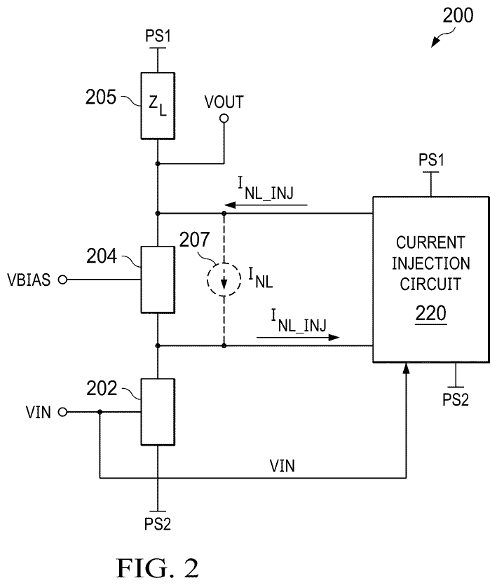

FIG. 2 illustrates an example cascode amplifier 200. Cascode amplifier 200 includes transistors 202 and 204, load device 205, and current injection circuit 220. Current source 207 in FIG. 2 is not an actual current source or device, but instead models the non-linear current I_{NL} conducted by transistor 204 in the operation of cascode amplifier 200.

FIG. 2 shows transistors 202 and 204 as generic three-terminal devices. Transistor 202 has a first current terminal coupled to power supply terminal PS2, and a control terminal coupled to input terminal IN. Transistor 204 has a first current terminal coupled to a second current terminal of transistor 202, and a control terminal receiving a bias voltage VBIAS. Load device 205 has a first terminal coupled to power supply terminal PS1, and a second terminal coupled to the second current terminal of transistor 204.

Transistors 202 and 204 may be implemented as metal-oxide-semiconductor (MOS) transistors of either of the p-channel (PMOS) or n-channel (NMOS) conductivity types, or as n-p-n or p-n-p type bipolar junction transistors (BJT). In this description for the case of transistors 202 and 204 implemented as MOS transistors, the first current terminal corresponds to the source terminal, the second current terminal corresponds to the drain terminal, and the control terminal corresponds to the gate terminal. For transistors 202 and 204 implemented as bipolar transistors, the first current terminal corresponds to the emitter terminal, the second current terminal corresponds to the collector terminal, and the control terminal corresponds to the base terminal.

Load device 205 may be a resistive load, a reactive load (e.g., resistor-capacitor network), an active load (e.g., a PMOS or NMOS current source, simple or cascode, etc.), or such other load device as suitable for the particular application of cascode amplifier 200.

Transistor 202 in the example of FIG. 2 is connected in common-source (MOS) or common-emitter (BJT) fashion, in that its first current terminal receives a power supply voltage or circuit ground, and its control terminal receives an input signal. Transistor 204 is connected in common-gate (MOS) or common-base (BJT) fashion, in that its control terminal receives a bias voltage, its first current terminal receives a signal from the second current terminal of transistor 202, and its second current terminal is coupled to load device 105 and presents an output signal at output terminal VOUT. Transistor 202 in cascode amplifier 200 may be referred to as the amplifier transistor or amplifier stage, and transistor 204 may be referred to as the cascode transistor or cascode stage.

As in the examples of FIGS. 1A and 1B described above, the current conducted by cascode transistor 204 in response to the input signal at input terminal VIN includes both a linear component and a non-linear component. The non-linear current conducted by cascode transistor 204 is modeled in FIG. 2 by current source 207 coupled between the first and second current terminals of transistor 204. As described above, “leakage” of this non-linear current through parasitic capacitances of transistors 202 and 204 could cause distortion in the signal at output terminal VOUT.

To reduce this distortion due to such leakage of non-linear cascode current I_{NL}, cascode amplifier 200 in this example includes current injection circuit 220. Current injection circuit 220 has an input coupled to input terminal VIN, and is biased from power supply terminals PS1 and PS2. Current injection circuit 220 has outputs coupled to the first and second current terminals of cascode transistor 204. As described in further detail below, current injection circuit 220 injects out-of-phase currents I_{NL_INJ} to the first and second current terminals of cascode transistor 204 in response to the input signal at terminal VIN. The amplitude and polarity of injected currents I_{NL_INJ} corresponds to that of the non-linear current I_{NL} conducted by cascode transistor 204.

The injected currents I_{NL_INJ} from the two outputs of current injection circuit 220 are “out-of-phase” relative to each other, based on the phase of the input signal at input terminal VIN. For example, if non-linear current I_{NL} conducted by cascode transistor 204 has a positive polarity during positive half-cycles of the input signal at terminal VIN, current injection circuit 220 conducts a positive polarity current I_{NL_INJ} into its output coupled to the first current terminal of cascode transistor 204. Conversely, if non-linear current I_{NL} conducted by cascode transistor 204 has a negative polarity during negative half-cycles of the input signal at terminal VIN, current injection circuit 220 conducts a negative polarity current I_{NL_INJ} into its output coupled to the second current terminal of cascode transistor 204.

The injected out-of-phase currents applied to cascode transistor 204 from current injection circuit 220 thus provide a “local” current loop for the non-linear current component I_{NL} conducted by cascode transistor 204. This local loop provides a conduction path directing non-linear current I_{NL} away from leaking through parasitic capacitances of both cascode transistor 204 and amplifier transistor 202, thus limiting the effect on the output signal caused by non-linear conduction at the cascode stage. Distortion in the output signal at high frequency operation can be reduced as a result.

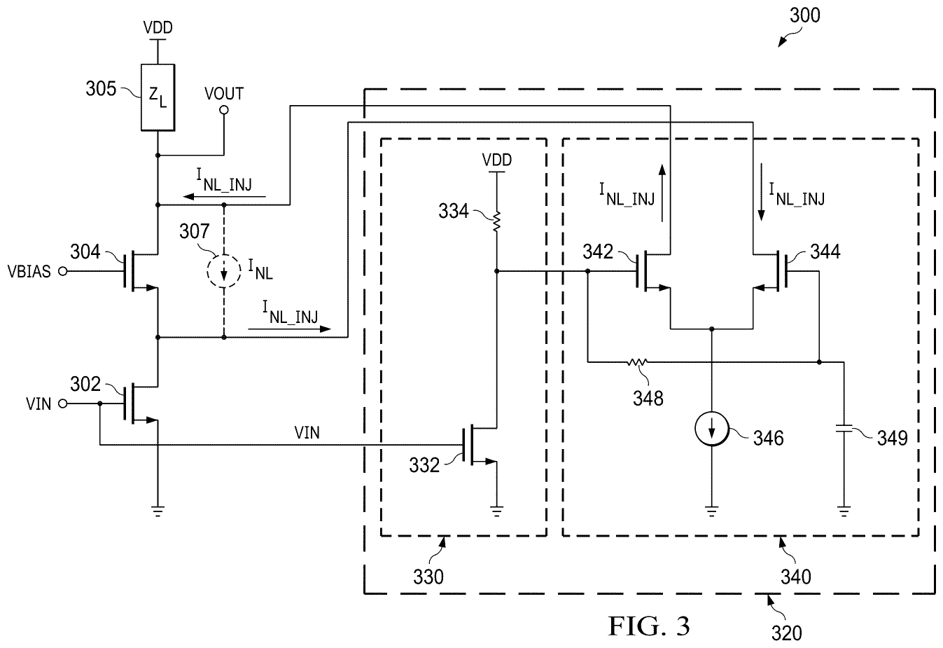

FIG. 3 illustrates an example cascode amplifer 300, including its current injection circuit 320, according to the architecture described above relative to FIG. 2 and implemented using n-channel MOS (NMOS) transistors. As mentioned above, cascode amplifier 300 may alternatively be implemented using PMOS or BJT transistors, with the power supply and bias voltages arranged accordingly.

Cascode amplifier 300 of FIG. 3 includes NMOS transistors 302, 304, load device 305, and current injection circuit 320. Current injection circuit 320 includes common-source amplifier 330 and differential amplifier 340. Common-source amplifier 330 includes NMOS transistor 332 and resistor 334. Differential amplifier 340 includes NMOS transistors 342, 344, current source 346, resistor 348, and capacitor 349.

In the example of FIG. 3 in which cascode amplifier 300 is implemented with NMOS transistors, the VDD power supply terminal corresponds to power supply terminal PS1 of FIG. 2, and a circuit ground terminal corresponds to power supply terminal PS2. For a PMOS implementation of cascode amplifier 300 of FIG. 3, ground and VDD power supply terminals would correspond respectively to power supply terminals PS1 and PS2 of FIG. 2.

NMOS transistor 302 in cascode amplifier 300 is connected in common-source fashion, with its source terminal coupled to the ground terminal and its gate terminal coupled to input terminal VIN. NMOS transistor 304 is connected in common-gate fashion, with its gate terminal coupled to bias terminal VBIAS, its source terminal coupled to the drain terminal of transistor 302, and its drain terminal coupled to output terminal VOUT and to a terminal of load device 305. In this example, NMOS common-source transistor 302 may be referred to as the amplifier transistor or amplifier stage, and NMOS common-gate transistor 304 may be referred to as the cascode transistor or cascode stage. Load device 205 may be a passive resistive or reactive load, an active load such as a current source, or such other load device suitable for the particular application.

As in the examples of FIGS. 1A, 1B and 2, the non-linear current conducted by NMOS cascode transistor 304 in response to the input signal at input terminal VIN is modeled in FIG. 3 by current source 307 coupled across the drain and source terminals of NMOS cascode transistor 304. Current injection circuit 320 is provided in cascode amplifier 300 of FIG. 3 to counteract distorting effects of this non-linear current I_{NL}.

As mentioned above, current injection circuit 320 includes common-source amplifier 330 and differential amplifier 340. Common-source amplifier 330 includes NMOS transistor 332 having a source terminal coupled to the circuit ground terminal, and a gate terminal coupled to input terminal VIN. A drain terminal of NMOS transistor 332 is coupled to one terminal of resistor 334. Resistor 334 has a second terminal coupled to the VDD power supply terminal. Resistor 334 serves as a load in common-source amplifier 330. The voltage at the drain terminal of NMOS transistor 332 responds to the input signal at input terminal VIN, such that common-source amplifier 330 amplifies the signal at input terminal VIN to a desired voltage swing at the drain of NMOS transistor 332.

NMOS transistors 342 and 344 of differential amplifier 340 have their source terminals coupled in common to one terminal of current source 346. Current source 346 has a second terminal coupled to the ground terminal in this NMOS implementation. The gate terminal of NMOS transistor 342 is coupled to the drain terminal of NMOS transistor 332 at the output of common-source amplifier 330, and the drain terminal of NMOS transistor 342 is coupled to the drain terminal of NMOS cascode transistor 304. Resistor 348 has one terminal coupled to the gate terminal of NMOS transistor 342, and a second terminal coupled to the gate terminal of NMOS transistor 344. NMOS transistor 344 has its drain terminal coupled to the source terminal of NMOS cascode transistor 304. Capacitor 349 has one terminal coupled to the gate terminal of NMOS transistor 344 and to resistor 348, and another terminal coupled to the ground terminal.

Differential amplifier 340 in this example is arranged in the form of an NMOS differential amplifier with its differential inputs coupled to the same input terminal, namely the output of common-source amplifier 330. As such, differential amplifier 340 of FIG. 3 may be considered as a “pseudo-differential amplifier.” Resistor 348 establishes a differential voltage across the gate terminals of NMOS transistors 342, 344. This differential voltage is reflected in the amplitude and polarities of non-linear current I_{NL_INJ} conducted by NMOS transistors 342 and 344. Because of the differential voltage across their gates, NMOS transistors 342, 344 conduct currents I_{NL_INJ} out-of-phase relative to one another, in response to the input signal at input terminal VIN.

Differential amplifier 340 may be implemented in forms other than a “pseudo-differential” arrangement, for example as a differential amplifier with two inputs and two outputs, a differential amplifier with two inputs and a single output, as a differential amplifier with a single input and single output, and other forms of differential amplifiers.

In the operation of current injection circuit 320, the input signal at input terminal VIN is amplified by common-source amplifier 330 to generate a differential voltage across the inputs of differential amplifier 340. In response, differential amplifier 340 generates injects out-of-phase injection currents I_{NL_INJ} that are applied to the source and drain terminals of NMOS cascode transistor 304. Injected current I_{NL_INJ} in a given phase of the input signal at terminal VIN is of the same polarity as the non-linear current I_{NL} conducted by NMOS cascode transistor 304 in that same input signal phase. The amplitude of injected current I_{NL_INJ} from differential amplifier 340 is determined by the gain of common-source amplifier 330. Ideally, the gain of common-source amplifier 330 is selected, for example by trimming resistor 334, so that the amplitude of the injected non-linear current I_{NL_INJ} from common-source amplifier 330 matches that of non-linear current I_{NL} conducted by NMOS cascode transistor 304.

For example, in the small-signal operation of cascode amplifier 300, positive half-cycles of the input signal at terminal VIN more strongly turn on both of NMOS transistors 302 and 332, increasing their drain-to-source currents. Non-linear conduction by NMOS cascode transistor 304 increases with the higher conduction of NMOS transistor 302, and can be modeled as a positive polarity of non-linear current component I_{NL} through current source 307. The stronger on-state of NMOS transistor 332 pulls the gate terminal of NMOS transistor 342 toward ground. This pulls the gate terminal of NMOS transistor 344 to a higher voltage than that of NMOS transistor 342, turning on NMOS transistor 344 more strongly than NMOS transistor 342. A positive injection current I_{NL_INJ} (in the small-signal sense) is thus conducted from the source terminal of NMOS cascode transistor 304 into the drain terminal of NMOS transistor 344, at an amplitude similar to that of non-linear current component I_{NL}.

Conversely, negative half-cycles of the input signal at terminal VIN tend to turn off NMOS transistors 302 and 332, reducing their drain-to-source currents. Non-linear conduction by NMOS cascode transistor 304 decreases, and in the small-signal sense, ca be modeled as a negative polarity of non-linear current component I_{NL} through current source 307. As NMOS transistor 332 turns off, the gate terminal of NMOS transistor 342 is pulled toward the VDD power supply through resistor 334. The gate terminal of NMOS transistor 342 is thus pulled to a higher voltage than that of NMOS transistor 344, turning on NMOS transistor 342 more strongly than NMOS transistor 344. A negative injection current I_{NL_INJ} (in the small-signal sense) is thus conducted into the drain terminal of NMOS transistor 342 from the drain terminal of NMOS cascode transistor 304, at an amplitude similar to that of non-linear current component I_{NL}.

As a result of this operation of current injection circuit 320, non-linear current I_{NL} of cascode transistor 304 is directed into differential amplifier 340, rather than leaking through both the parasitic gate-to-source capacitance of cascode transistor 304 and also the parasitic drain-to-source capacitance of amplifier transistor 302. Intermodulation distortion of cascode amplifier 300 is reduced as a result.

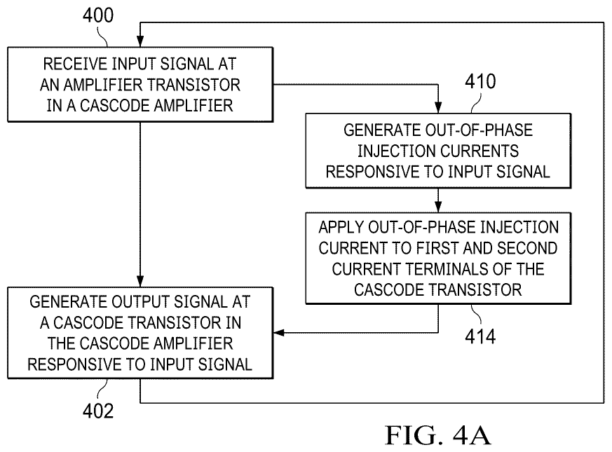

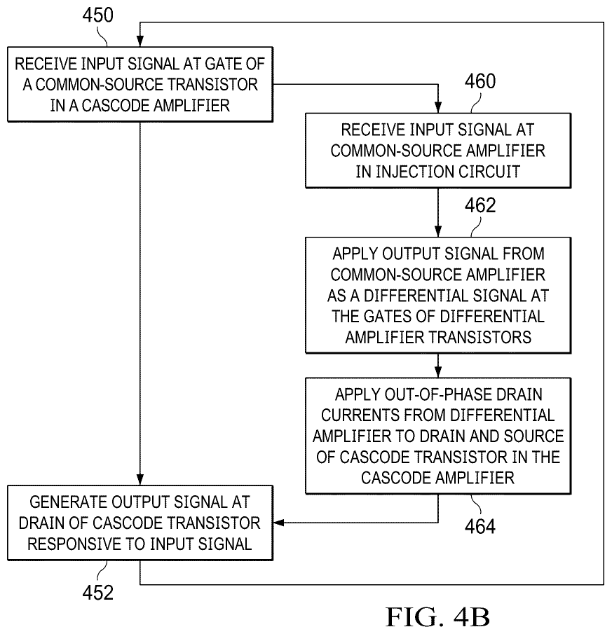

FIG. 4A illustrates an example method of reducing the non-linear effects of the cascode transistor of cascode amplifier 200 of FIG. 2. In process block 400, an input signal is received at the control terminal of an input transistor, such as the gate or base terminal of amplifier transistor 202 in cascode amplifier 200. During process block 400, the appropriate power supply voltages are applied at power supply terminals PS1, PS2 as suitable for the particular type of transistors implementing cascode amplifier 200, and the appropriate bias voltage is applied to bias terminal VBIAS.

In process block 402, cascode amplifier 200 generates an output signal from cascode transistor 204 in response to the input signal applied to amplifier transistor 202. In the example of FIG. 2, the output signal is generated at output terminal VOUT, which is coupled to the second current terminal of cascode transistor 204 and to load device 205.

Meanwhile, in process block 410, current injection circuit 220 generates out-of-phase injection currents I_{NL_INJ} in response to the input signal at input terminal VIN. In this example, the out-of-phase injection currents I_{NL_INJ} are generated in process block 410 from one of the two outputs of current injection circuit 220 depending on the input signal phase, at an amplitude corresponding to the amplitude of non-linear current I_{NL} conducted by cascode transistor 204 of cascode amplifier 200.

In process block 414, current injection circuit 220 applies out-of-phase injection currents I_{NL_INJ} to one of the first and second current terminals of cascode transistor 204 according to the phase of the input signal at terminal VIN. For example, during the input signal phases in which the non-linear current I_{NL} of cascode transistor 204 is positive (as shown in FIG. 2), current injection circuit 220 conducts a current I_{NL_INJ} from the first current terminal of cascode transistor 204 (at the node between cascode transistor 204 and amplifier transistor 202). During input signal phases in which the non-linear current I_{NL} of cascode transistor 204 is negative (as shown in FIG. 2), current injection circuit 220 injects a current I_{NL_INJ} at (conducts a negative current I_{NL_INJ} from) the second current terminal of cascode transistor 204 (at the node between cascode transistor 204 and load device 205).

As evident in FIG. 2, process blocks 410 and 414 are performed concurrently with process blocks 400 and 402. In operation, the out-of-phase injection currents I_{NL_INJ} applied to cascode transistor 204 in process block 414 respond to the input signal at input terminal VIN in real time along with the output signal generated by cascode amplifier 200 at output terminal VOUT.

FIG. 4B illustrates an example method of reducing the non-linear effects for the more particular example of cascode amplifier 300 of FIG. 3. The process blocks shown in FIG. 4B thus correspond to those shown in FIG. 4A and described above.

Referring to cascode amplifier 300 of FIG. 3, an input signal is received at input terminal VIN, and thus at the gate terminal of NMOS common-source transistor 302, in process block 450. At the time of process block 450, the appropriate power supply voltages are received at power supply terminal VDD with reference to circuit ground, and at the ground terminal coupled to the source terminal of NMOS transistor 302. In addition, the appropriate bias voltage is received at bias terminal VBIAS and thus at the gate of NMOS cascode transistor 304, which is coupled in a common-gate arrangement. In process block 452, cascode amplifier 300 generates an output signal from the drain terminal of cascode transistor 304, at output terminal VOUT, in response to the input signal applied in process block 450.

Meanwhile, in process block 460, the input signal at input terminal VIN is also received at the gate terminal of NMOS transistor 332 in common-source amplifier 330 in current injection circuit 320. As mentioned above, common-source amplifier 330 applies a gain (an inverting gain in this example) to the input signal, based on the gain of NMOS transistor 332 and the resistance of resistor 334. This gain can be selected to generate a voltage swing at the drain terminal of NMOS transistor 332 setting the amplitude of out-of-phase injection currents I_{NL_INJ} from differential amplifier 340.

In process block 462, the output signal from common-source amplifier 330 in response to the input signal at input terminal VIN is applied to differential amplifier 340. In the example of differential amplifier 340 of FIG. 3, resistor 348 establishes a differential voltage signal across the gate terminals of NMOS transistors 342 and 344 based on the output signal from common-source amplifier 330. In response to this differential voltage signal, NMOS transistors 342 and 344 conduct injection currents I_{NL_INJ} at their drain terminals out-of-phase with one another, and in response to the phase of the input signal at input terminal VIN. By setting the gain of common-source amplifier 330 as described above, the amplitude of the out-of-phase injection currents I_{NL_INJ} can correspond to the amplitude of non-linear current I_{NL} conducted by cascode transistor 304.

In process block 464, current injection circuit 220 applies out-of-phase injection currents I_{NL_INJ} to the drain and source terminals of cascode transistor 304 according to the phase of the input signal at terminal VIN. For example, during the input signal phases in which the non-linear current I_{NL} of cascode transistor 304 is positive (as shown in FIG. 3), NMOS transistor 342 conducts injection current I_{NL_INJ} from the source terminal of cascode transistor 304. Conversely, during input signal phases in which the non-linear current I_{NL} of cascode transistor 304 is negative, NMOS transistor 344 conducts a current I_{NL_INJ} from the drain terminal of cascode transistor 304. As a result, current injection circuit 320 provides a current path for non-linear current I_{NL} conducted by cascode transistor 304 in the operation of cascode amplifier 300.

As in the example of FIG. 4A, process blocks 460, 462, and 464 are performed concurrently with process blocks 450 and 452.

The examples described above enable significant improvement in the linearity of cascode amplifiers. This improvement is evident in a reduction in the intermodulation distortion over frequency. A common measure of intermodulation distortion in circuits that are weakly non-linear, such as cascode amplifiers in which the current through the cascode transistor has a non-linear component, is the output third-order intercept point (OIP3). The OIP3 is a figure of merit associated with third-order intermodulation distortion, and compares the distortion power of caused by third-order non-linear conduction to the output power of the linearly amplified input signal. The OIP3 is mathematical in that it is based on extrapolations of the output power versus input power characteristics, on a logarithmic scale, for both the output power and the third-order nonlinear product, to determine the crossing point.

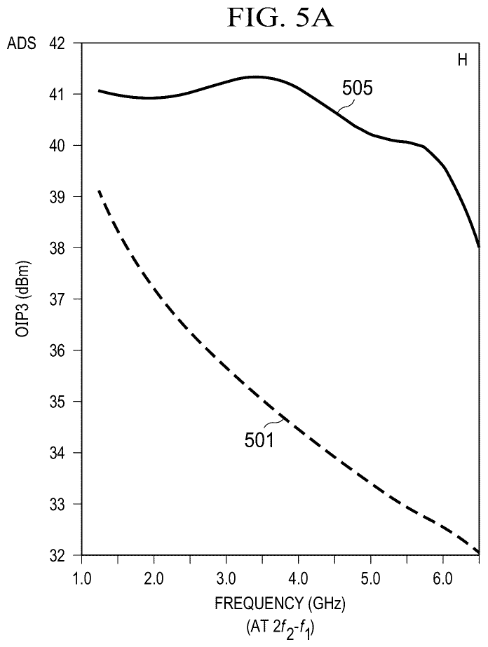

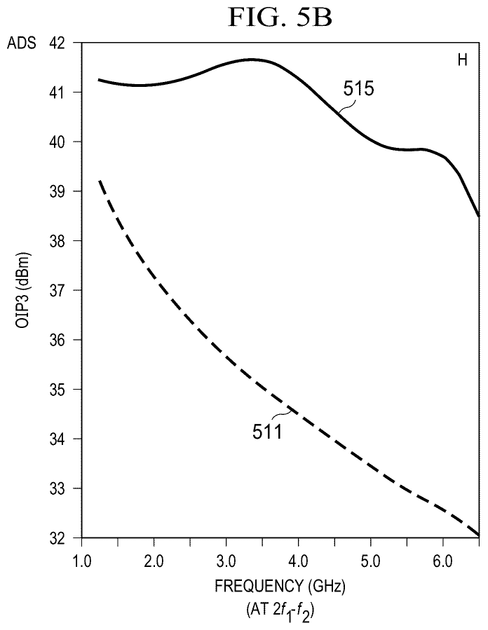

FIG. 5A and FIG. 5B compare the OIP3 over frequency of example cascode amplifier 300 of FIG. 3 with that of prior art cascode amplifier 150 of FIG. 1B. The example plots of FIGS. 5A and 5B are based on simulation of the amplifiers in response to two input tones at a fixed frequency offset (e.g., constant |f₁−f₂|) over center frequencies ranging from 1 GHz to 6.5 GHZ. FIG. 5A illustrates the OIP3 comparison for the intermodulation frequency (2f₂−f₁), and FIG. 5B illustrates the OIP3 comparison for the intermodulation frequency (2f₁−f₂).

Plot 501 in FIG. 5A and plot 511 in FIG. 5B illustrate the OIP3 behavior of a prior art cascode amplifier such as described above relative to FIG. 1B over frequencies ranging from about 1.2 GHz to about 6.5 GHZ. Plot 505 in FIG. 5A and plot 515 in FIG. 5B illustrate the OIP3 behavior of a cascode amplifier such as described above relative to FIG. 3, over the same frequency range. As evident from FIGS. 5A and 5B, OIP3 is improved at the high-end frequency of 6.5 GHz by about 6.5 dB, such that the overall OIP3 of the amplifier is 38 dBm or better over the entire frequency range.

The examples described above thus enable significant improvement in the linearity of cascode amplifiers, particularly those operating at high frequencies. Such improvement is attained due to a reduction in the amount of non-linear current conducted by the cascode device that is injected to the amplifier output. This improvement can be reflected by significant improvement in measures such as OIP3. In addition, the examples described above can be implemented in an efficient manner, from the standpoint of power consumption. For example, some implementations of these examples attain these advantages while requiring as little as about 20% of the bias current of the cascode device.

Examples are described in this specification as implemented into cascode amplifiers such as used in high frequency applications, such as communications or spectrum analysis, as such implementation can be advantageous in that context. However, aspects of these examples may be beneficially applied in a wide range of applications, and by way of various transistor technologies. Accordingly, the above description is provided by way of example only, and is not intended to limit the true scope as claimed.

As used herein, the terms “terminal”, “node”, “interconnection” and “pin” are used interchangeably. Unless specifically stated to the contrary, these terms are generally used to mean an interconnection between or a terminus of a device element, a circuit element, an integrated circuit, a device, or other electronics or semiconductor component.

Unless otherwise stated, “about,” “approximately,” or “substantially” preceding a value means +/−10 percent of the stated value. Modifications are possible in the described examples, and other examples are possible within the scope of the claims.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including one or more semiconductor elements (such as transistors) one or more passive elements (such as resistors, capacitors, and/or inductors) and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party. While, in some example embodiments, certain elements are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

Modifications are possible in the described examples, and other examples are possible, within the scope of the claims.

What is claimed is:

1. A circuit, comprising:
a first transistor having a first terminal coupled to a first power supply terminal, a second terminal, and a control terminal coupled to an input terminal;
a second transistor having a first terminal coupled to the second terminal of the first transistor, a second terminal coupled to an output terminal, and a bias terminal coupled to a bias terminal; and
a current injection circuit having an input coupled to the input terminal, a first output coupled to the second terminal of the second transistor, and a second output coupled to the first terminal of the second transistor.

2. The circuit of claim 1, further comprising:
a load device having a first terminal coupled to the second terminal of the second transistor, and a second terminal coupled to a second power supply terminal of the circuit.

3. The circuit of claim 1, wherein the current injection circuit comprises:
a third transistor having a first terminal, a second current terminal coupled to the second terminal of the second transistor, and a control terminal coupled to the input terminal;
a fourth transistor having a first terminal, a second terminal coupled to the first terminal of the second transistor, and a control terminal;
a current source having a first terminal coupled to the first power supply terminal, and a second terminal coupled to the first terminals of the third and fourth transistors; and
a first resistor having a first terminal coupled to the control terminal of the third transistor, and a second terminal coupled to the control terminal of the fourth transistor.

4. The circuit of claim 3, wherein the current injection circuit further comprises:
a fifth transistor having a first terminal coupled to the first power supply terminal, a second terminal coupled to the control terminal of the third transistor and to the first terminal of the first resistor, and a control terminal coupled to the input terminal;
a second resistor having a first terminal coupled to the second power supply terminal and a second terminal coupled to the second terminal of the fifth transistor; and
a capacitor having a first terminal coupled to the control terminal of the fifth transistor, and a second terminal coupled to the first power supply terminal.

5. The circuit of claim 3, wherein the first, second, third, fourth, and fifth transistors are n-channel metal-oxide semiconductor (MOS) transistors;
wherein the first power supply terminal receives a common potential;
and wherein the second power supply terminal receives a positive potential relative to the common potential.

6. The circuit of claim 3, wherein the first, second, third, fourth, and fifth transistors are p-channel MOS transistors;
wherein the second power supply terminal receives a common potential;
and wherein the first power supply terminal receives a positive potential relative to the common potential.

7. The circuit of claim 3, wherein the first, second, third, fourth, and fifth transistors are bipolar junction transistors.

8. A cascode amplifier, comprising:
an amplifier transistor having a first terminal receiving a first power supply voltage, a second terminal, and a control terminal receiving an input signal;
a cascode transistor having a first terminal coupled to the second terminal of the amplifier transistor, a second terminal coupled to an output terminal; and a control terminal receiving a bias voltage; and
a current injection circuit having an input receiving the input signal, and first and second outputs coupled to the first and second terminals of the cascode transistor, respectively, the current injection circuit configured to present out-of-phase currents from its first and second outputs responsive to the input signal.

9. The cascode amplifier of claim 8, further comprising:
a load device having a first terminal coupled to the second terminal of the cascode transistor, and a second terminal coupled to a second power supply terminal of the circuit.

10. The cascode amplifier of claim 9, wherein the current injection circuit comprises:
an amplifier having an input coupled to the input terminal, and having an output; and
a differential amplifier, having first and second inputs coupled to the output of the amplifier to establish a differential voltage between the first and second inputs, and having first and second outputs coupled to the second and first terminals of the cascode transistor, respectively.

11. The cascode amplifier of claim 10, wherein the differential amplifier comprises:
a first transistor having a first terminal, a second terminal corresponding to the first output of the differential amplifier coupled to the second terminal of the cascode transistor, and a control terminal corresponding to the first input of the differential amplifier coupled to the output of the second amplifier;
a second transistor having a first terminal, a second terminal corresponding to the second output of the differential amplifier coupled to the first terminal of the cascode transistor, and a control terminal corresponding to the second input of the differential amplifier;
a current source receiving a first power supply voltage and coupled to the first terminals of the first and second transistors;
a first resistor coupled between the control terminals of the first and second transistors.

12. The cascode amplifier of claim 11, wherein the amplifier comprises:
a third transistor having a first terminal receiving the first power supply voltage, a second terminal coupled to the control terminal of the first transistor, and a control terminal receiving the input signal;
a second resistor receiving a second power supply voltage and coupled to the second terminal of the third transistor; and
a capacitor receiving the first power supply voltage and coupled to the control terminal of the second transistor.

13. The cascode amplifier of claim 12, wherein the input, cascode, first, second, and third transistors are n-channel metal-oxide semiconductor (MOS) transistors;
wherein the first power supply terminal receives a common potential;
and wherein the second power supply terminal receives a positive potential relative to the common potential.

14. The cascode amplifier of claim 12, wherein the input, cascode, first, second, and third transistors are p-channel MOS transistors;
wherein the second power supply terminal receives a common potential;
and wherein the first power supply terminal receives a positive potential relative to the common potential.

15. The cascode amplifier of claim 12, wherein the input, cascode, first, second, and third transistors are bipolar junction transistors.

16. A method, comprising:
receiving an input signal at an amplifier transistor in a cascode amplifier, the cascode amplifier further including a cascode transistor coupled to the input transistor;
responsive to the input signal, generating out-of-phase injection currents from first and second outputs of a current injection circuit;
applying the out-of-phase injection currents to first and second current terminals of the cascode transistor; and
generating an output signal from an output of the cascode amplifier responsive to the input signal.

17. The method of claim 16, wherein the receiving of an input signal at an amplifier transistor comprises:
receiving the input signal at a gate terminal of a common-source transistor in the cascode amplifier;
and wherein the generating of an output signal comprises:
generating an output signal at a drain terminal of the cascode transistor.

18. The method of claim 17, wherein the generating of out-of-phase injection currents comprises:
receiving the input signal at a common-source amplifier;
applying an output signal from the common-source amplifier as a differential voltage to gate terminals of first and second differential amplifier transistors;
and wherein the applying of the opposing phase compensation current comprises:
applying currents from drain terminals of the first and second differential amplifier transistors to a source terminal and the drain terminal, respectively, of the cascode transistor.
